(19) United States
(12) Patent Application Publication
(10) Pub. No.: US 2009/0140790 A1
(43) Pub. Date: Jun. 4, 2009

(54) ELECTRONIC DEVICE WITH COMPOUND AUDIO INTERFACE AND POWER ADAPTER

(75) Inventors: CHANG-CHUN LIU, Shenzhen (CN); XIAO-LIN GAN, Shenzhen (CN); YU-KUANG HO, Tu-Cheng (TW)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/960,712

(22) Filed: Dec. 20, 2007

(30) Foreign Application Priority Data
Nov. 29, 2007 (CN) 200710202779.5

(51) Int. Cl. H03K 17/00

(52) U.S. Cl. 327/407

(57) ABSTRACT

An exemplary electronic device includes a power module having an anode and a cathode; an audio module having a first audio signal terminal, a second audio signal terminal and a ground terminal; and an audio socket having a first audio signal terminal, a second audio signal terminal connected to the second audio terminal of the audio module, and a ground terminal, wherein the first audio terminal of the audio socket is selectively connected to the anode of the power module and the first audio signal terminal of the audio module via a first switch, the ground terminal of the audio socket is selectively connected to the cathode of the power module and the ground terminal of the ground module of the audio module via a second switch. Therefore, users can charge the electronic device via the audio interface.

### CROSS-REFERENCES TO RELATED APPLICATION

Relevant subject matter is disclosed in a co-pending U.S. patent application (Attorney Docket No. US17430) filed on the same date and having a same title, which is assigned to the same assignee as this patent application.

### BACKGROUND

1. Field of the Invention

The present invention relates to electronic devices, and particularly to an electronic device with a compound audio interface and a power adapter.

2. Description of Related Art

Conventionally, many different interfaces are arranged in an electronic device such as MP3, MP4, mobile telephone and so on, for example USB interface, audio interface, charger interface and so on. These interfaces are arranged in the electronic device for different purposes and each has a special standard.

Referring to FIG. 4, a conventional electronic device includes an audio module 10, a power module 20, an audio socket 30, and a power connector 40. The audio module 20 includes two audio signal terminals 12 and 14, and a ground terminal 16. The power module 20 includes an anode 22 and a cathode 24. The audio socket 30 includes two audio signal terminals 32 and 34, and a ground terminal 36. The power connector 40 includes an anode 42 and a cathode 44. The audio signal terminals 32 and 34, and the ground terminal 36 of the audio connector are connected to the audio signal terminals 12 and 14, and the ground terminal 16 respectively. The anode 42 and cathode 44 are connected to the anode 22 and cathode 24 respectively. Therefore, the audio connector is used to transmit audio signals between the electronic device and another device, the power connector is used to connect to a charger.

### SUMMARY

An exemplary electronic device includes a power module having an anode and a cathode; an audio module having a first audio signal terminal, a second audio signal terminal, and a ground terminal; and an audio socket having a first audio signal terminal, a second audio signal terminal connected to the second audio terminal of the audio module, and a ground terminal, wherein the first audio terminal of the audio socket is selectively connected to the anode of the power module and the first audio signal terminal of the audio module via a first switch, the ground terminal of the audio socket is selectively connected to the cathode of the power module and the ground terminal of the ground module of the audio module via a second switch.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is a schematic diagram of an electronic device with a compound audio interface in accordance with an embodiment of the present invention;

FIG. 2 is a schematic diagram of a power adapter of the electronic device.

FIG. 3 is a circuit diagram of FIG. 2; and

FIG. 4 is a schematic diagram of a conventional electronic device.

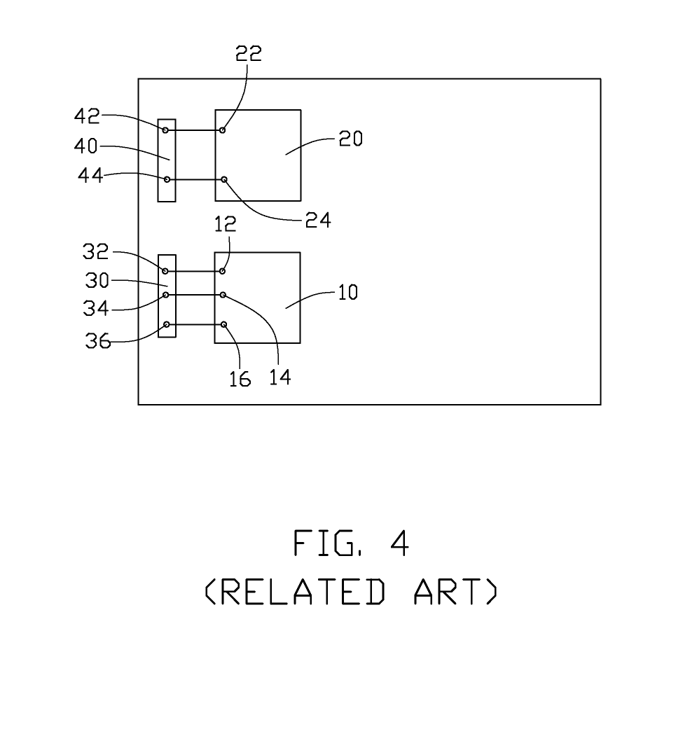

### DETAILED DESCRIPTION

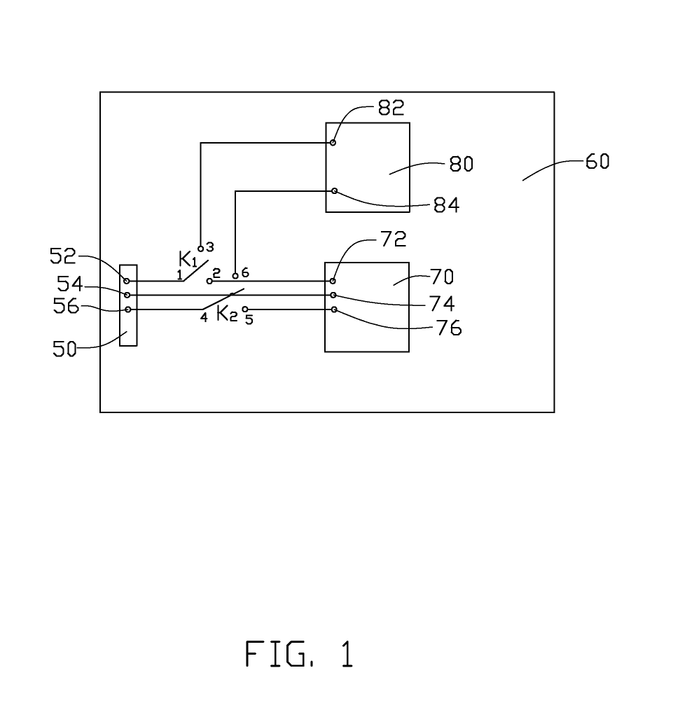

Referring to FIG. 1, an electronic device 60 in accordance with an embodiment of the present invention includes an audio socket 50, an audio module 70, and a power module 80, and two single-pole double-throw switches K1 and K2. The audio socket 50 includes a first audio signal terminal 52, a second audio signal terminal 54, and a ground terminal 56. The audio module 70 includes two audio signal terminals 52 and 54, and a ground terminal 56. The power module 80 includes an anode 82 and a cathode 84.

The first audio signal terminal 52 of the audio socket 50 is connected to the pole 1 of the switch K1, the throws 2 and 3 are connected to the audio signal terminal 72 of the audio module 70 and the anode 82 of the power module 80 respectively. The second audio signal terminal 54 of the audio socket 50 is connected to the audio signal terminal 74 of the audio module 70. The ground terminal 56 of the audio socket 50 is connected to the pole 4 of the switch K2, the throws 5 and 6 are connected to the ground terminal 76 of the audio module 70 and the cathode 84 of the power module 80 respectively. The switches K1 and K2 can be operated by a button exposed through the frame of the electronic device 60.

Therefore, users can selectively couple the audio socket 50 with the audio module 70 or the power module 80 of the electronic device 60 by operating the switches K1 and K2 manually.

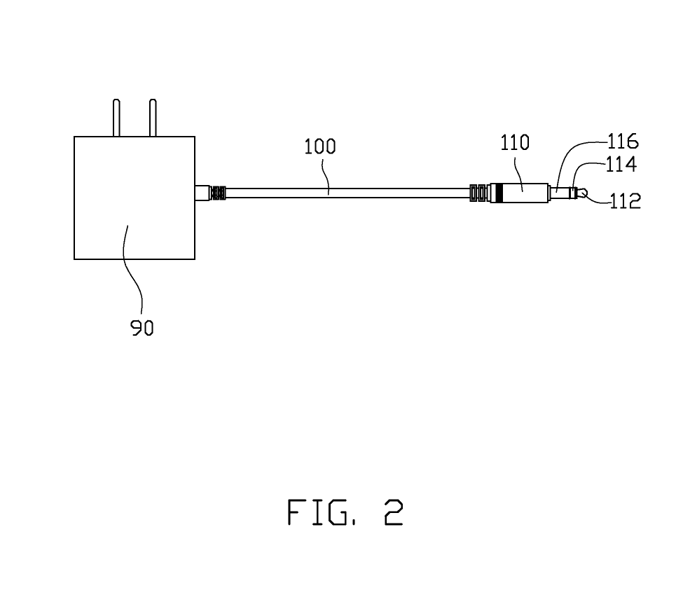

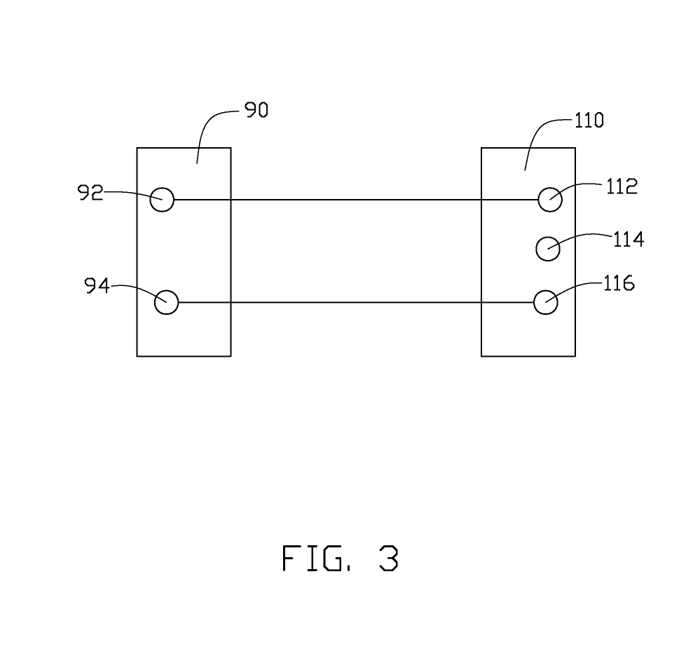

Referring to FIG. 2 and FIG. 3, a power adapter includes an adapter module 90, a cable 100, and an audio plug 110. The adapter module 90 includes an anode 92 and a cathode 94. The audio plug 110 includes a first audio signal terminal 112, a second audio signal terminal 114, and a ground terminal 116, wherein the first audio signal terminal 112 and the ground terminal 116 are connected to the anode 92 and the cathode 94 of the adapter module 90 via the cable 100. Therefore, the power adapter can charge the electronic device 60 by plugging the audio plug 110 into the audio socket 50 while the audio socket 50 is coupled with the power module 80 of the electronic device 60 via the switches K1 and K2.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device comprising:
a power module having an anode and a cathode;
an audio module having a first audio signal terminal, a second audio signal terminal and a ground terminal; and
an audio socket having a first audio signal terminal, a second audio signal terminal connected to the second audio terminal of the audio module, and a ground terminal, wherein the first audio terminal of the audio socket is selectively connected to the anode of the power module and the first audio signal terminal of the audio module via a first switch, the ground terminal of the audio socket is selectively connected to the cathode of the power module and the ground terminal of the ground module of the audio module via a second switch.

2. The electronic device as claimed in claim 1, wherein the first and second switches are single-pole double-throw switches.

3. The electronic device as claimed in claim 1 further comprising a power adapter comprising:
an adapter module having an anode and a cathode; and
an audio plug arranged to plug into the audio socket, the audio plug having an audio signal terminal and a ground terminal connected to the anode and the cathode of the adapter respectively.

4. The electronic device as claimed in claim 1, wherein the first and second switches are operated by a button exposed through a frame of the electronic device.
